(19) United States
(12) Patent Application Publication
(10) Pub. No.: US 2023/0207710 A1
(43) Pub. Date: Jun. 29, 2023

(54) SYSTEM, METHOD, AND CIRCUIT FOR HIGH-VOLTAGE PACKAGES

(71) Applicant: Analog Devices, Inc., Wilmington, MA (US)

(72) Inventors: Noe QUINTERO, Los Gatos, CA (US); Brian Hamilton, Menlo Park, CA (US)

(73) Assignee: Analog Devices, Inc., Wilmington, MA (US)

(21) Appl. No.: 18/065,323

(22) Filed: Dec. 13, 2022

Related U.S. Application Data
(60) Provisional application No. 63/294,023, filed on Dec. 27, 2021.

(51) Int. Cl. H01L 31/02; H01L 31/107; H01L 25/16; G01S 7/4863

(52) U.S. Cl. CPC H01L 31/02005; H01L 31/107; H01L 25/167; G01S 7/4863

(57) ABSTRACT

Techniques, methods, and systems are provided for packaging high-voltage packages. On example system package includes circuitries comprising circuit elements; and a plurality of connection pins including low-voltage pins; input/output (IO) pins arranged in regions proximate edges of the system package; and high-voltage pins arranged in an inner region of the system package away from all edges of the system package.

### CROSS REFERENCE TO RELATED APPLICATIONS

The present application claims priority to and the benefit of the U.S. Provisional Patent Application No. 63/294,023 entitled “HIGH VOLTAGE PACKAGE FOR LIDAR BIAS” and filed Dec. 27, 2021, which is hereby incorporated by reference in its entirety as if fully set forth below and for all applicable purposes.

### FIELD OF THE DISCLOSURE

The present disclosure relates to system packaging, and more specifically to techniques, methods, and systems for providing high-voltage packages.

### BACKGROUND

Many electronic devices tend to require much more sophisticated power supplies for supplying power. For example, many electronics may require high frequency, high overall efficiency, fewer components, and/or low ripple in the power supplied by the power supplies. More specifically, there is often a need for a power supply circuit that is capable of delivering power with high-voltage components (fast changing voltage and current) with stable, clean power conversion and delivery.

### BRIEF DESCRIPTION OF THE DRAWINGS

The present disclosure is best understood from the following detailed description when read with the accompanying figures. It is emphasized that, in accordance with the standard practice in the industry, various features are not necessarily drawn to scale, and are used for illustration purposes only. Where a scale is shown, explicitly or implicitly, it provides only one illustrative example. In other embodiments, the dimensions of the various features may be arbitrarily increased or reduced for clarity of discussion.

For a fuller understanding of the nature and advantages of the present invention, reference is made to the following detailed description of preferred embodiments and in connection with the accompanying drawings, in which:

FIG. 1 illustrates an exemplary packaging layout for a power supply system;

FIG. 2 illustrates an exemplary packaging layout for a power supply system, in accordance with some embodiments of the disclosure provided herein;

FIG. 3 depicts an exemplary diagrammatic view of a power supply circuit including two separate alternating current/direct current (AC/DC) pathway signals, in accordance with some embodiments of the disclosure provided herein;

FIG. 4 illustrates an exemplary schematic of a power supply system configured to supply power to a sensor array, in accordance with other embodiments of the disclosure provided herein;

FIG. 5 illustrates an exemplary packaging layout for a power supply system, in accordance with other embodiments of the disclosure provided herein; and

FIG. 6 illustrates an exemplary schematic of a power supply circuit including two separate AC/DC pathway signals, in accordance with other embodiments of the disclosure provided herein.

### DETAILED DESCRIPTION

The systems, methods, and devices of this disclosure each have several innovative aspects, no single one of which is solely responsible for all the desirable attributes disclosed herein. Details of one or more implementations of the subject matter described in this specification are set forth in the description below and the accompanying drawings.

For purposes of illustrating pin layout for high-voltage pins in integrated circuit (IC) packages or system packages proposed herein, it might be useful to first understand phenomena that may come into play in high-voltage printed circuit board (PCB) design. The following foundational information may be viewed as a basis from which the present disclosure may be properly explained. Such information is offered for purposes of explanation only and, accordingly, should not be construed in any way to limit the broad scope of the present disclosure and its potential applications.

A PCB is used to mechanically support and electrically connect electronic components using conductive pathways, tracks or signal traces etched from metal sheets (e.g., copper sheets) laminated onto a non-conductive substrate (e.g., insulating material). High-voltage PCB design has rigorous rules on spacing between traces and/or components. In general, if the normal operating voltage of a product exceeds about 30 volts AC power (VAC) or 60 volts DC power (VDC), then it may be desirable for a designer to be diligent about satisfying the high-voltage PCB spacing rules. When designing high-density, high-voltage boards, satisfying high-voltage PCB spacing rules can become even more important. Various PCB trace spacing requirements may already be in place to prevent signal integrity problems, but these spacing requirements are also important to prevent arc discharge. The high density makes spacing much trickier, and even more important for protection.

In general, spacing is more important in high-voltage PCB design than lower voltage PCB design because a potential difference between conductive elements on a board can create an arc, for example, if the voltage between the conductors exceeds a certain breakdown voltage. Any arc that does occur poses a significantly higher risk to both the product and users. To help mitigate that risk, there are standards for two primary spacing measurements in PCB design: clearance and creepage distance.

Creepage and clearance are terms used to define distances between conductors in a PCB layout and are specified in safety standards, such as the International Electrotechnical Commission (IEC) 61010-1 document. Creepage and clearance are defined as the spacing between two neighboring conductors, although they are defined in two different ways.

Clearance may refer to the shortest distance through air between two conductors. Its definition can be thought of by an overhead clearance, for example, how much room in the air before an object strikes its environment. If the clearance anywhere on a PCB is too small, then an over-voltage event can cause an arc between neighboring conductive elements on the board.

The PCB layout rules for clearance may vary with the material, voltage, and environmental conditions. The environmental effects can be significant. Most commonly, humidity may change the breakdown voltage of air and affects the likelihood of arcing. Dust may be another factor, since particulates that collect on the surface of the PCB can form a track over time, shortening the distance between conductors.

Similar to clearance, creepage measures the distance between conductors on high-voltage PCB. However, instead of measuring the distance in air, creepage measures the shortest distance along the surface of the insulation material on the PCB. Board material and environment can also affect creepage requirements. Moisture or particulate accumulation on the board can shorten creepage distance the same way they do for clearance.

Creepage can be difficult to meet in a high-density PCB design. Since moving traces is rarely the first choice, there are a couple other ways for increasing the surface distance in a design. For instance, adding either a slot between traces, or a vertical barrier of insulation, the creepage distance can be significantly increased without changing the trace layout on the board. However, this can increase the area usage on the board, and thus may be undesirable.

In some examples, an IC package may have high-voltage pins (for inputs or outputs). These high-voltage pins may require extra space to meet creepage distance. For instance, if the high-voltage pins are arranged along or near edge(s) of the IC package, then a PCB including such an IC package cannot have other components mounted in proximity to the IC package so that PCB creepage and/or clearance requirements can be met. Stated differently, such an IC package may rely on board area outside of the IC package to meet the PCB creepage and/or clearance requirements. Accordingly, there is a need to improve packaging for high-voltage IC packages. As used herein, an IC package may include one or more IC devices. In some examples, such an IC package may be referred to as a micro-module, a system-in-package (SIP), or a system package.

The present disclosure relates to packaging a circuit system with a high output voltage. More specifically, this disclosure describes techniques, methods, and systems for providing a compact way to package a high-voltage power supply (e.g., a direct current (DC) power supply), for example, for biasing avalanche photodiodes (APDs) or any other suitable components. To that end, high-voltage pins of the package are arranged at about the center of the package (e.g., away from the edges of the package) so that the creepage distance is met within the package itself rather than outside of the package, sacrificing PCB area. Accordingly, the disclosed embodiments can provide for a safer, more robust, and compact high-voltage package. As used herein, a high voltage may refer to a voltage that can range from about 0 V to about −400V, about 0 V to about −375 V, or generally above a certain threshold (e.g., in the order of hundreds of volts).

According to an aspect of the present disclosure, a system package may include circuitries including various circuit elements. In an aspect, the circuitries may be for generation of a high output voltage. Additionally, the circuitries may be for controlling or configuring the output voltage level. Additionally or alternatively, the circuitries may be for reading back configurations and/or statuses related to the output voltage. The system package may further include a plurality of connection pins. The plurality of connection pins may include low-voltage pins, input/output (IO) pins, and high-voltage pins. The IO pins may be arranged in regions proximate edges of the system package. In contrast, the high-voltage pins may be arranged in an inner region of the system package away from all edges of the system package. That is, none of the high-voltage pins may be placed along or near the edges of the system package. In an aspect, the system package may receive an input voltage (e.g., a first voltage) via at least one of the low-voltage pins (e.g., a first low-voltage pin) and provide an output voltage (e.g., a second voltage) based on the input voltage via at least one of the high-voltage pins (e.g., a first high-voltage pin). The output voltage may be significantly higher than the input voltage, for example, by many orders. Further, the output voltage can have a polarity opposite the input voltage. In an example, the input voltage may be between about 0 Volt (V) to about 42 V and the output voltage can be up to about −400V or at about −375 V.

In some aspects, the high-voltage pins may be arranged such that a distance between an individual high-voltage pin of the high-voltage pins and an edge of the system package may satisfy a predetermined creepage distance. The predetermined creepage distance can be dependent on the level of a voltage output by the individual high-voltage pin and/or an operating condition associated with the system package. In some examples, the predetermined creepage distance may be defined by a safety standard (e.g., the IEC 61010-1).

In some aspects, the plurality of connection pins may further include a group of ground pins in a region of the system package between the IO pins and the high-voltage pins, for example, to isolate the IO pins from the high-voltage pins.

In some aspects, the IO pins may include at least one of a control pin or a data signal pin associated with serial communication (e.g., a serial peripheral interface (SPI)). Additionally or alternatively, the IO pins may include at least one control pin for controlling an output voltage at the high-voltage pins. Additionally or alternatively, the IO pins may include at least one control pin for controlling a current associated with an output voltage at the high-voltage pins. Additionally or alternatively, the IO pins may include at least one readout pin for reading a configuration associated with an output voltage at the high-voltage pins.

In some aspects, the system package can further include a temperature indicator. In some aspects, the system package may be a ball grid array (BGA) package. Accordingly, the plurality of connection pins may be in the form of solder balls and may be arranged according to a placement grid.

According to a further aspect of the present disclosure, the system package may include a plurality of IC devices. For instance, the circuitries discussed above may be part of the IC devices. In some aspects, the plurality of IC devices may include a negative power boost (or inverting power boost converter) IC device in which the first low-voltage pin may be coupled to an input of the negative power boost IC device and the first high-voltage pin may be coupled to an output of the negative power boost IC device. In some aspects, the plurality of IC devices may further include an SPI device. Additionally or alternatively, the plurality of IC devices may include one or more digital-to-analog converters (DACs) and/or one or more analog-to-digital converters (ADCs). Additionally or alternatively, the plurality of IC devices may include at least one of an amplifier or a comparator device. In general, the plurality of IC devices can include any suitable IC devices.

According to a further aspect of the present disclosure, a system may include the system package as discussed above and an array of APDs, where the system package may be used to provide a bias voltage for driving the APDs. To that end, one or more of the high-voltage pins may be coupled to the APDs. In some aspects, the APDs may be part of a light detection ranging (LIDAR) device.

The systems, schemes, and mechanisms described herein advantageously provide a compact way of packaging an IC device or module that includes high-voltage pin(s) while complying to a safety standard (e.g., meeting creepage and/or clearance requirements). By satisfying creepage and/or clearance within the system package or module, a PCB including such an system package or module can allow other components to be mounted in proximity to the system package or module that would otherwise require a larger space or gap between the other components and the system package or module.

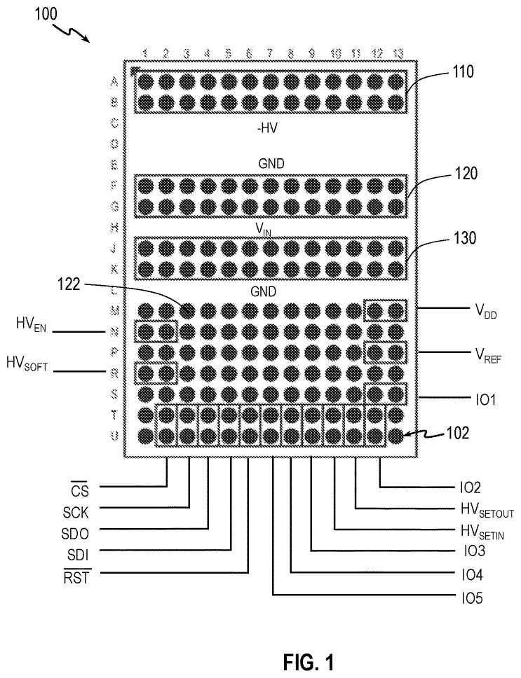

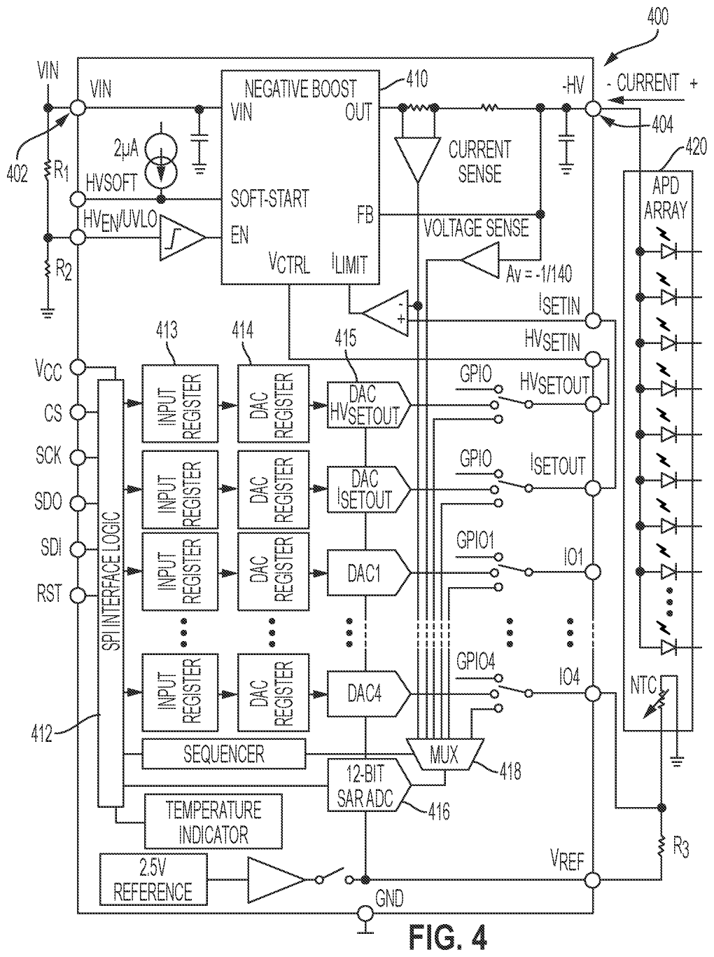

FIG. 1 illustrates an exemplary packaging layout for a power supply system 100. The system 100 is in the form of a BGA package (e.g., a power supply system package). As shown in FIG. 1, the BGA package may include arrays of connections or balls 102 (only one of which is labeled with a reference numeral in FIG. 1 in order to not clutter the drawing). The adjacent connections 102 that are bounded within a rectangular box may be shorted to provide redundancy (e.g., to increase reliability). As further shown in FIG. 1, the BGA package may include high-voltage connections 110 (shown by −HV in which the negative sign indicates that the high voltage has a negative polarity), ground connections 120 (shown by GND), input voltage connections 130 (shown by V_{IN}), and various control and signaling balls or connections (e.g., the input/output (IO) connections arranged along edges of the BGA package). As shown, the IO connections may include chip select (CS) bar, reset (RST) bar, serial data out (SDO), serial data in (SDI), serial clock (SCK)), HV_{SETOUT}, HV_{SETIN}, HV_{EN}, HV_{SOFT}, IO1, IO2, IO3, IO4, IO5, V_{REF}, V_{DD}. The BGA package may also include other ground connections 122. An example schematic of the BGA package is shown in FIG. 4 and details about the connections 102 will be discussed more fully below with reference to FIG. 4.

A BGA is a type of surface-mount packaging (a chip carrier) used for ICs. BGA packages are used to permanently mount devices such as microprocessors. A BGA can provide more interconnection pins than can be put on a dual in-line or flat package. The whole bottom surface of the device can be used, instead of just the perimeter. The traces connecting the package's leads to the wires or balls which connect the die to package are also on average shorter than with a perimeter-only type, leading to better performance at high speeds.

As one in the art can appreciate, HV balls are disposed at the top of the BGA package. Pursuant to creepage requirements, GND balls are disposed some distance away with no intervening balls. In some embodiments, balls can populate this area yet won't be used. In other embodiments, pins may be skipped.

The inventor has recognized a shortcoming of the present design. In that, the distance directly above the HV balls cannot be used when packaging with another device/component, e.g., a lead-on frame. Creepage distances must be maintained on and off board.

While FIG. 1 illustrates the system 100 in the form of a BGA package, the system 100 can be packaged in any suitable form. The connections 102 may generally be referred to as connection pins.

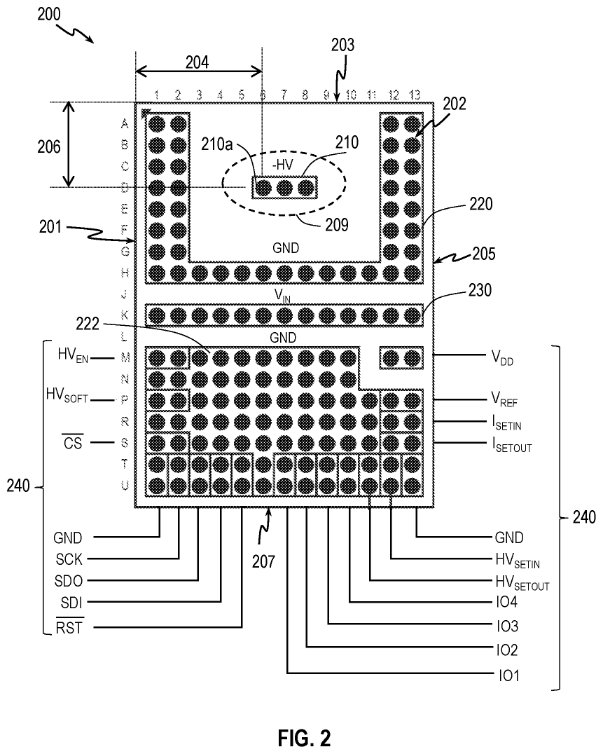

FIG. 2 illustrates an exemplary packaging layout for a power supply system 200, in accordance with some embodiments of the disclosure provided herein. The system 200 is in the form of a BGA package including arrays of connections or balls 202 (only one of which is labeled with a reference numeral in FIG. 2 in order to not clutter the drawing). The BGA package for the system 200 may include similar connections as the BGA package for the system 100, but the placement of the connections may be different. As shown in FIG. 2, the BGA package for the system 200 may include high-voltage connections 210 (shown by −HV), ground connections 220 (shown by GND), input voltage connections 230 (shown by V_{IN}), and various other control and signaling balls (e.g., IO connections 240 along edges of the package similar to the IO connections shown in FIG. 1) disposed on a common plane. Further, the package for the system 200 may have other ground connections 222. An example schematic of the BGA package is shown in FIG. 4 and details of the connections 202 will be discussed more fully below with reference to FIG. 4.

Comparing FIG. 2 to FIG. 1, the high-voltage connection pins 210 are disposed within the package (e.g., in an inner region of the package). That is, the high-voltage pins 210 are not disposed on or near the package's edges (or away from the package's edges). This way the creepage distance can be met inside the package itself. In some embodiments, the ground pins 220 may surround the high-voltage pins 210, while maintaining the creepage distance. In other embodiments, the ground pins 220 may surround the high-voltage pins 210 in semicircular manner. In yet other embodiments, the ground pins 220 may be arrays which straddle the high-voltage pins 210. In general, the ground pins 220 may be placed such that the high-voltage pins 210 may be isolated from the IO pins 240.

Pursuant to creepage requirements, GND balls (e.g., the connections 122 of FIG. 1 or the connections 222 of FIG. 2) can be disposed at some distances away with no intervening connection. In some embodiments, connectors can populate in this area yet won't be used. In other embodiments, connectors may be skipped.

In general, the BGA package (the power supply system package) for the system 200 shown in FIG. 2 may include circuitries including various circuit elements. In an aspect, the circuitries may be for generation of a high output voltage. Additionally, the circuitries may be for controlling or configuring the output voltage level. Additionally or alternatively, the circuitries may be for reading back configurations and/or statuses related to the output voltage. The package may further include a plurality of connection pins 202 coupled to the circuitries. The plurality of connection pins 202 may be arranged on a common plane of the system package. The plurality of connection pins 202 may include input voltage pins 230 (e.g., low-voltage pins), IO pins 240, and high-voltage pins 210 (e.g., output voltage pins). The IO pins 240 may be arranged in regions proximate edges 201, 203, 205, and 207 of the system package. The high-voltage pins 210 may be arranged in an inner region 209 of the package away from all edges (e.g., the edges 201, 203, 205, 207) of the system package. That is, none of the high-voltage pins 210 may be placed along or near the edges 201, 203, 205, or 207 of the system package. In an aspect, the system package may receive an input voltage (e.g., a first voltage) via at least one of the low-voltage pins 230 (e.g., a first low-voltage pin) and provide an output voltage (e.g., a second voltage) based on the input voltage via at least one of the high-voltage pins 210 (e.g., a first high-voltage pin). The output voltage may be higher than the input voltage by many orders, for example. Further, the output voltage can have a polarity opposite the input voltage. For instance, the system package may include negative power booster circuitries. In an example, the input voltage may be between 0 V to about 42 V and the output voltage can be up to about −400V. In some aspects, the high-voltage pins 210 are configured to output a voltage between about 0 V and about −400 V. In some aspects, the high-voltage pins 210 are configured to output a voltage at about −375 V.

In some aspects, the high-voltage pins 210 may be arranged such that a distance (e.g., shown by 206 and 204) between an individual high-voltage pin 210a of the high-voltage pins 210 and an edge of the system package (e.g., the distance 206 from the pin 201a to the edge 201 or the distance 204 from the pin 201a to the edge 203) may satisfy a predetermined creepage distance associated with a voltage output by the individual high-voltage pin 210a. In some examples, the predetermined creepage may be based on a certain standard (e.g., the IEC 61010-1) and can be further based on an operating condition (e.g., the operating voltage and/or environmental factors) of the package. For instance, the IEC 61010-1 document specifies that for pollution degree 2, a creepage distance may be set to 2.0 millimeter (mm) for an operating voltage of 400V.

In some aspects, the plurality of connection pins 202 may further include a group of ground pins 220 in a region of the package between the IO pins 240 and the high-voltage pins 210, for example, to isolate (thermally) the IO pins 240 from the high-voltage pins 210.

In some aspects, the IO pins 240 may include at least one of a control pin (e.g., the CS bar and RS bar pins), a data signal pin (e.g., the SDI and SDO pins), or a clock pin (e.g., the SCK pins) associated with serial communication (e.g., the SPI logic). Additionally or alternatively, the IO pins 240 may include at least one control pin (e.g., HV_{EN}, HV_{SETIN}, and HV_{SOFT}) for controlling an output voltage at the high-voltage pins 210. Additionally or alternatively, the IO pins 240 may include at least one control pin (e.g., I_{SETIN}) for controlling a current associated with an output voltage at an individual pin of the high-voltage pins 210. Additionally or alternatively, the IO pins 240 may include at least one readout pin (e.g., HV_{SETOUT}, and I_{SETOUT}) for reading back configuration associated with an output voltage at the high-voltage pins 210.

In some aspects, the system package can further include a temperature indicator. In some aspects, the system package may be a BGA package. Accordingly, the plurality of connection pins 202 may be in the form of solder balls and may be arranged according to a placement grid.

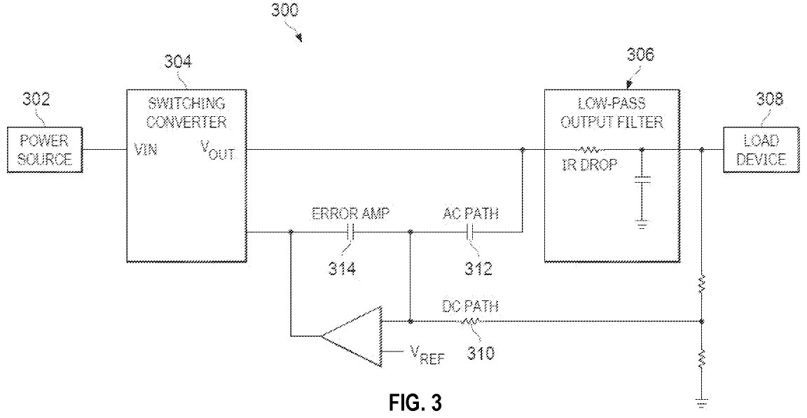

FIG. 3 depicts an example diagrammatic view of a power supply circuit 300 including two separate pathway signals, in accordance with some embodiments of the disclosure provided herein. In this non-limiting example, power supply circuit 300 comprises a power source 302, a switching converter 304, a low pass filter (LPF) 306, a DC path 310 (which can form a resistor ladder), an error amp 314, and an AC path 312 (which can include one or more capacitors).

In the present embodiment, the switching converter is a boost converter. A boost converter (step-up converter) is a DC-to-DC power converter that steps up voltage (while stepping down current) from its input (supply) to its output (load). It is a class of switched-mode power supply (SMPS) containing at least two semiconductors (a diode and a transistor) and at least one energy storage element: a capacitor, inductor, or the two in combination. To reduce voltage ripple, filters made of capacitors (sometimes in combination with inductors) are normally added to such a converter's output (load-side filter) and input (supply-side filter).

Power for the boost converter can come from any suitable DC source, such as batteries, solar panels, rectifiers, and DC generators. A process that changes one DC voltage to a different DC voltage is called DC-to-DC conversion. A boost converter is a DC-to-DC converter with an output voltage greater than the source voltage. A boost converter is sometimes called a step-up converter since it “steps up” the source voltage. Since power (P=VI) must be conserved, the output current is lower than the source current.

In one or more embodiments, filter is an LPF. An LPF is a filter that passes signals with a frequency lower than a selected cutoff frequency and attenuates signals with frequencies higher than the cutoff frequency. The exact frequency response of the filter depends on the filter design. The filter is sometimes called a high-cut filter, or treble-cut filter in audio applications. An LPF is the complement of a high-pass filter (HPF).

LPFs exist in many different forms, including electronic circuits such as a hiss filter used in audio, anti-aliasing filters for conditioning signals prior to analog-to-digital conversion, digital filters for smoothing sets of data, acoustic barriers, blurring of images, and so on. The moving average operation used in fields such as finance is a particular kind of LPF, and can be analyzed with the same signal processing techniques as are used for other LPFs. LPFs provide a smoother form of a signal, removing the short-term fluctuations and leaving the longer-term trend.

In general, the LPF can be a first order resistor-capacitor (RC) LPF. However, second or higher order filters are not beyond the scope is not beyond the scope of the present disclosure. As is noted through the present disclosure, an IR drop may occur across the resistor (shown by R) in the current configuration. This produces an undesirable phase delay particularly at higher switching frequencies.

In practice, switching converter provides an output voltage Vₒᵤₜ to filter which is then delivered to a load device. The DC component is fed back from after the resistor, in order to compensate for the IR drop. An additional feedback path (AC) is provided before the resister and/or filter. The high frequency pathway before the dominate RC pole improves supply performance and increases circuit stability under a much wider range of poles. The present topology can tolerate large pole changes more than 100× in changes for the output frequency response when properly tuned.

In one or more embodiments, the error amp 314 is a differential amplifier. A differential amplifier is a type of electronic amplifier that amplifies the difference between two input voltages but suppresses any voltage common to the two inputs. It is an analog circuit with two inputs in which the output is ideally proportional to the difference between the two voltages:

Vₒᵤₜ=A(Vᵢₙ⁺−Vᵢₙ⁻)

where A is the gain of the amplifier.

Single amplifiers are usually implemented by either adding the appropriate feedback resistors to a standard opamp, or with a dedicated IC containing internal feedback resistors. It is also a common sub-component of larger ICs handling analog signals.

Error amplifier compares the recombination of the AC and DC signals with a reference voltage V_{ref}. In one or more embodiments, the reference voltage V_{ref} is set to a bias voltage of load device. In other embodiments, the output is a scaled version of reference V_{ref}. In some embodiments, reference voltage V_{ref} can be adjusted, particularly in transient conditions, such as, from thermal drift, gain change, and voltage coefficient.

FIG. 4 illustrates an exemplary schematic of a power supply system 400 configured to supply power to a sensor array 420, in accordance with other embodiments of the disclosure provided herein. The system 400 may correspond to the system 100 of FIG. 1 or the system 200 of FIG. 2. For instance, the system 400 may be packaged as shown in FIG. 1. Alternatively, the system 200 may be packaged as shown in FIG. 2 in which high-voltage pins are arranged in an inner region of the package to meet a certain creepage within the package itself.

As shown in FIG. 4, the system 400 may include a power supply 410 (the negative boost), SPI interface logic 412, input registers 413, DAC registers 414, DACs 415, successive approximation register (SAR) ADC 416, multiplexer (MUX) 418 and their associated pinout interfaces. The pinout interfaces may have connections corresponding to the connections (e.g., high-voltage connections, input voltage connections, IO connections) shown FIGS. 1 and 2. In operation, high voltage is supplied to the −HV pinout (e.g., the high-voltage pins 210). In one or more embodiments, this is used to reverse bias an array of avalanche photodiode (APD) of the sensor array 420.

An avalanche photodiode (APD) is a highly sensitive semiconductor photodiode that exploits the photoelectric effect to convert light into electricity. From a functional standpoint, they can be regarded as the semiconductor analog of photomultipliers. Typical applications for APDs are laser rangefinders, long-range fiber-optic telecommunication, and quantum sensing for control algorithms. Other applications may include, but are not limited to, positron emission tomography and particle physics. APD arrays are becoming commercially available, also lightning detection and optical SETI may be future applications. In some instances, adding a graphene layer to APDs can prevent degradation over time to APDs like new, which is important in shrinking their size and costs for many diverse applications & bringing devices out of vacuum tubes into digital age.

By applying a high reverse bias voltage (typically 100-200 V in silicon), APDs show an internal current gain effect (around 100) due to impact ionization (avalanche effect). However, some silicon APDs may employ alternative doping and beveling techniques compared to traditional APDs that allow greater voltage to be applied (>1500 V) before breakdown is reached and hence a greater operating gain (>1000). In general, the higher the reverse voltage, the higher the gain. Among the various expressions for the APD multiplication factor (M), an instructive expression is given by the formula:

$$M = \frac{1}{1 - {\int }_{0}^{L} α ( x ) dx} ,$$

where L is the space-charge boundary for electrons, and a is the multiplication coefficient for electrons (and holes). This coefficient has a strong dependence on the applied electric field strength, temperature, and doping profile. Since APD gain varies strongly with the applied reverse bias and temperature, it is necessary to control the reverse voltage to keep a stable gain. Avalanche photodiodes therefore are more sensitive compared to other semiconductor photodiodes.

If very high gain is needed, detectors related to APDs (single-photon avalanche diodes) can be used and operated with a reverse voltage above a typical APD's breakdown voltage. In this case, the photodetector needs to have its signal current limited and quickly diminished. Active and passive current-quenching techniques have been used for this purpose. Single-photon avalanche photodiode (SPADs) that operate in this high-gain regime are sometimes referred to being in Geiger mode. This mode is particularly useful for single-photon detection, provided that the dark count event rate and after-pulsing probability are sufficiently low.

In some embodiments, the system 400 includes an adjustable current limiter. This affords an additional level of safety, particularly in different voltage output in various applications. For example, a user can lower the current limit when going from a 300V to 400V application. The current limiter can be digital or analog. Additionally, the system 400 provides for additional stability while using external capacitive loads, which are common in the art, since any added capacitance will reduce the 3 decibels (dB) bandwidth of the output pole.

Essentially having extra capacitor(s) on the output will produce a larger RC time constant. This would normally make stabilizing the error amp loop even harder to do since a larger delay in the feedback is detrimental to stability. Since the patent circuit takes the AC path before this pole, any changes to increase the RC time constant is immune with this circuit.

In operation, the system 400 can be controllable via SPI for communicating with a chipset or other controller devices. SPI is an interface bus commonly used to send data between microcontrollers and small peripherals such as shift registers, sensors, and SD cards. It uses separate clock and data lines, along with a select line to choose the device you wish to talk to. The SPI is a synchronous serial communication interface specification used for short distance communication, primarily in embedded systems.

SPI devices communicate in full-duplex mode using a primary-secondary architecture with a single primary. In contrast to devices employing simplex communication whereby data is only pushed in one direction, a full-duplex (FDX) system, or sometimes called double-duplex, allows communication in both directions, and, unlike half-duplex, allows this to happen simultaneously. As an example, land-line telephone networks are full-duplex since they allow both callers to speak and be heard at the same time. Modern cell phones are also full-duplex.

Primary/secondary architecture is a model of communication where one device or process has unidirectional control over one or more other devices. In some systems a primary is selected from a group of eligible devices, with the other devices acting in the role of secondaries. The primary device originates the frame for reading and writing. Multiple secondary devices are supported through selection with individual secondary select (SS) lines.

More specifically, devices communicate using a primary/secondary relationship, in which the primary initiates the data frame, as follows. When the primary generates a clock and selects a secondary device, data may be transferred in either or both directions simultaneously. In fact, as far as SPI is concerned, data are always transferred in both directions. It is up to the primary and secondary devices to know whether a received byte is meaningful or not. So, a device must discard the received byte in a “transmit only” frame or generate a dummy byte for a “receive only” frame.

Sometimes SPI is called a four-wire serial bus, contrasting with three-, two-, and one-wire serial buses. The SPI may be accurately described as a synchronous serial interface, but it is different from the Synchronous Serial Interface (SSI) protocol, which is also a four-wire synchronous serial communication protocol. But SSI Protocol employs differential signaling and provides only a single simplex communication channel.

SPI devices are useful because the receiving hardware can be implemented as a simple shift register. This is a much simpler (and cheaper) piece of hardware than the full-up UART (Universal Asynchronous Receiver/Transmitter) that asynchronous serial requires.

Referencing back to FIG. 4, another advantage the current architecture provides is a guaranteed output voltage set precision over temperature. Specifically, the present embodiment can accommodate and adjust changes due to drift and other undesirable effects of temperature.

The present state of the art doesn't offer a stable power supply over a broad range of voltages. The instant embodiment can produce stable voltage in the hundreds of volts, plus or minus. In a preferred embodiment, the range is 0V to −375V. The system yields high voltage measurement precision with a high current measurement precision.

Other system features include accuracy over current loading; extra IOs used to simplify system design (e.g., TIAs, etc.); wide operating range (input voltage to output voltage ratio); high input voltage range allows for higher efficiency; built-in package creepage and clearance at the output pin to shrink solution size; built in GPIO/DACs, ADCs; negative voltage generation, as needed; and ecosystem with adjustable TIA.

In some aspects, the system 400 may receive an input voltage at a connection 402 (shown by VIN, e.g., corresponding to one of the input voltage pins 230 of FIG. 2). The negative boost device 410 may generate a high output voltage (with an opposite polarity to the input voltage) based on the input voltage and output the high voltage at a connection 404 (shown by −HV, e.g., corresponding to one of the high-voltage pins 210 of FIG. 2). In an example, the input voltage at the connection 402 may be within a range between about 5 V to about 12 V, or about 5V to about 42 V, and the output voltage at the connection 404 may be within a range between about −300 V and −400 V. In some instances, the negative boost device 410 may generate and output the high output voltage when the input voltage is at a certain voltage level, for example, at the node shown by H_{EN}. Stated differently, if the input voltage at the connection 402 is below a certain threshold voltage, the negative boost device 410 may be shutoff and may not output a high voltage at the connection 404.

In some aspects, the system 400 may allow a user to configure and/or control the voltage level and/or current sensitivity of the high output voltage at the connection 404. To that end, a microcontroller, controller, or any processor be in communication with the system 400 and may write a control word via the SPI interface logic 412 (e.g., IO pins shown by CS bar, RS bar, SDI, and SCK), an input register 413, a DAC register 414, and a corresponding DAC 415 may convert the control word to an analog signal, which may configure and/or control the negative boost device 410. For instance, a control word converted by the DAC 415 labeled with HV_{SETOUT} may be converted to a signal (where connection HV_{SETOUT} may be shorted to connection HV_{SETIN}) for controlling a voltage level, and a control word converted by the DAC 415 labeled with I_{SETOUT} may be converted to a signal (where connection I_{SETOUT} may be shorted to connection I_{SETIN}) for controlling a current limit. In some aspects, instead of controlling the voltage level and/or current limit via the SPI interface logic 412, the voltage level and/or the current limit can be directly controlled via IO pins shown by HV_{SETIN} and I_{SETIN}, respectively.

In some aspects, the system 400 may allow a user to read back a configuration of the system 400. To that end, a microcontroller, controller, or any processor in communication with the system 400 may read a configuration via the SPI interface logic 412 (e.g., IO pins shown by CS bar, RS bar, SDO, and SCK). For instance, a voltage level of the high output voltage and/or a current related to the high output voltage can be sensed and converted by the ADC 416 into a digital word and provided to the SPI interface logic 412 for readback.

In some aspects, the system 400 may generate a reference voltage internally, for example, for operating the DACs 415 and/or ADC 416. Alternatively, the system 400 may receive a reference voltage via the IO pin V_{REF}.

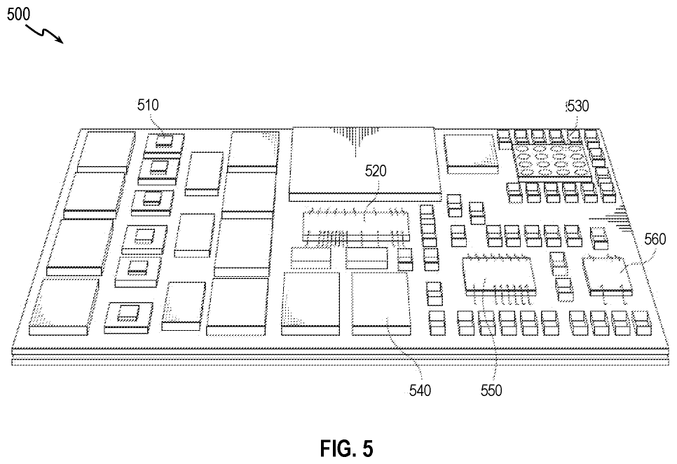

FIG. 5 illustrates an example packaging layout for a power supply system 500, in accordance with other embodiments of the disclosure provided herein. The layout comprises a high voltage charge pump 510, a boost device 520 (e.g., a negative power boost device), an ADC/DAC/REF circuit 530, high precision resistors 540, an operational amplifier 550, and a comparator 560.

An operational amplifier (often referred to as an ‘op amp’ or ‘opamp’) is a DC-coupled high-gain electronic voltage amplifier with a differential input and, usually, a single-ended output. In this configuration, an op amp produces an output potential (relative to circuit ground) that is typically 100,000 times larger than the potential difference between its input terminals. Operational amplifiers had their origins in analog computers, where they were used to perform mathematical operations in linear, non-linear, and frequency-dependent circuits.

A comparator is a device that compares two voltages or currents and outputs a digital signal indicating which is larger. It typically has two analog input terminals and one binary digital output. A comparator comprises a specialized high-gain differential amplifier. They are commonly used in devices that measure and digitize analog signals, such as successive approximation (SAR) ADCs, as well as relaxation oscillators.

In some aspects, the system 500 may correspond to the system 200 of FIG. 2 and the system 400 of FIG. 4. For instance, the circuitries in the system 400 may be included in multiple IC devices and the IC devices can be packaged into a BGA package as shown in FIG. 2. In an example, the boost device 520 may correspond to the negative boost device 410. The ADC/DAC/REF circuit 530 may be part of the system 400.

In some aspects, the system 500 may be a package (e.g., power supply system package, micro-module, or SIP) including a plurality of IC devices. The IC devices may include a negative power boost IC device (e.g., the boost device 520). The package may further include a plurality of connection pins on a common plane of the system package, for example, arranged as shown in FIG. 2. The plurality of connection pins may include one or more low-voltage pins (e.g., the input voltage pins 230) to receive a first voltage. The one or more low-voltage pins may be coupled to an input of the negative power boost IC device. The plurality of connection pins may further include one or more high-voltage pins (e.g., high-voltage pins 210) to output a second voltage based on the first voltage. The one or more high-voltage pins may be coupled to an output of the negative power boost IC device and disposed on an inner region of the common plane away from edges of the system package. In some aspects, the second voltage is between about 0 V and about −400 V. In some aspects, the plurality of connection pins may further include a group of ground pins (e.g., the ground connections 220) surrounding the high-voltage pins (e.g., in a semicircular manner or surrounding at least 3 sides of the group of high-voltage pins). In some aspects, the plurality of IC devices may further include an SPI device. In some aspects, the plurality of IC devices may further include at least one of an ADC (e.g., the ADC 416) or a DAC (e.g., the DACs 415). In some aspects, the plurality of IC devices may further include at least one of an amplifier IC device (e.g., the amplifier 550) or a comparator IC device (e.g., the comparator 560). In some aspects, one of the one or more high-voltage pin may coupled to an array of APDs (e.g., the sensor array 420) and an output voltage (e.g., a high output voltage) at the high-voltage pin may drive or bias the APDs.

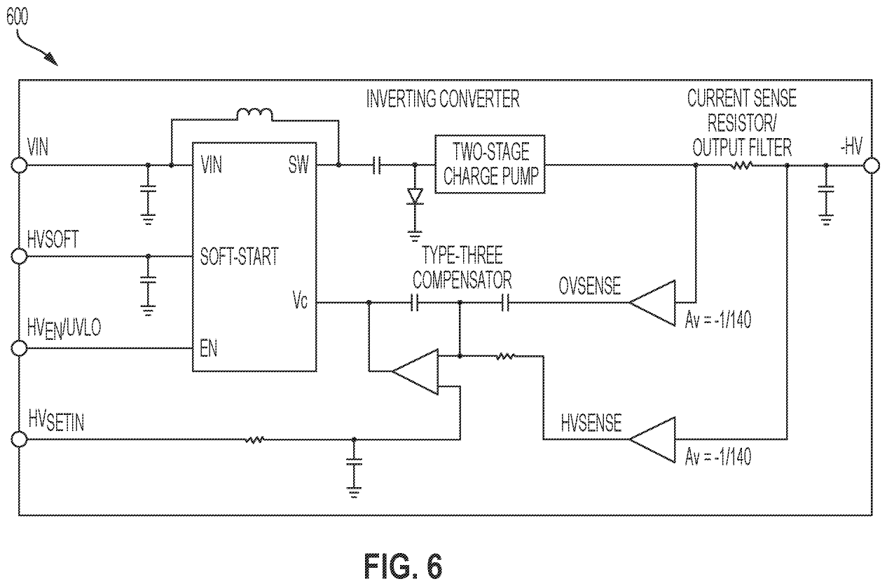

FIG. 6 illustrates an exemplary schematic of a power supply circuit 600 including two separate AC/DC pathway signals, in accordance with other embodiments of the disclosure provided herein. Power supply circuit comprises power source, inverting converter, ground diode, 2-stage charge pump, over voltage sense amp, high-voltage sense amp, set voltage resistor and capacitor, type 3 compensator, current sense resistor, and output capacitor, which form the output filter. In some aspects, the power supply circuit 600 may correspond to the boost device 520 of FIG. 5 or the negative boost device 410 of FIG. 4.

In some embodiments, the inductor is used in switching conversion. The capacitor and diode are implemented to crate the inverting converter. In other embodiments and architectures positive supplies can be crated. The stage charge pumped is used to increase the boost ratio. One skilled in the art will appreciate the charge pump is unnecessary is no increase in boost in need. Similarly, it can be replaced with a transformer.

The AC/DC amplifiers can be used as generic attenuators/inverters. In other embodiments, resistor divider (e.g., voltage ladder) with a negative reference can produce the same function. Additionally, one can split the function with a resister divider and an inverting amp, or any combination thereof. The type 3 compensator is the feedback capacitor to create the error amp, in some embodiments.

The embodiments described and illustrated herein are not meant by way of limitation, and are rather exemplary of the kinds of features and techniques that those skilled in the art might benefit from in implementing a wide variety of useful products and processes. For example, in addition to the applications described in the embodiments relating to switched power conversion, those skilled in the art would appreciate that the present disclosure can be applied to buck, boost, buck-boost, linear regulator and other DC-DC power conversion topologies. However, it is to be appreciated that the present exemplary embodiments are also amenable to other like applications and inputs, such as, alternating currents and voltages.

While many embodiments focus on biasing avalanche photodiodes, other light detecting devices are not beyond the scope of the present disclosure, such as, photosensors. Photosensitive elements are sensors of light or other electromagnetic energy. In some embodiments, the photosensitive elements are photodetector which have p-n junctions that converts light photons into current. The absorbed photons make electron-hole pairs in the depletion region, which is used to detect received light intensity. In some other embodiments, photodetector are photodiodes or phototransistors.

Other light detecting means are not beyond the scope of the disclosure either. For example, in addition to APDs, SPADs and photomultipliers tubes (PMTS) are not beyond the scope of the present can be used.

A SPAD is a solid-state photodetector within the same family as photodiodes and APDs, while also being fundamentally linked with basic diode behaviors. As with photodiodes and APDs, a SPAD is based around a semiconductor p-n junction that can be illuminated with ionizing radiation such as gamma, x-rays, beta and alpha particles along with a wide portion of the electromagnetic spectrum from ultraviolet (UV) through the visible wavelengths and into the infrared (IR).

In a photodiode, with a low reverse bias voltage, the leakage current changes linearly with absorption of photons, i.e., the liberation of current carriers (electrons and/or holes) due to the internal photoelectric effect. However, in a SPAD, the reverse bias is so high that a phenomenon called impact ionization occurs which is able to cause an avalanche current to develop. Simply, a photo-generated carrier is accelerated by the electric field in the device to a kinetic energy which is enough to overcome the ionization energy of the bulk material, knocking electrons out of an atom.

A large avalanche of current carriers grows exponentially and can be triggered from as few as a single photon-initiated carrier. A SPAD is able to detect single photons providing short duration trigger pulses that can be counted. However, they can also be used to obtain the time of arrival of the incident photon due to the high speed that the avalanche builds up and the device's low timing jitter.

The fundamental difference between SPADs and APDs or photodiodes, is that a SPAD is biased well above its reverse-bias breakdown voltage and has a structure that allows operation without damage or undue noise. While an APD is able to act as a linear amplifier, the level of impact ionization and avalanche within the SPAD has prompted researchers to liken the device to a Geiger-counter in which output pulses indicate a trigger or “click” event. The diode bias region that gives rise to this “click” type behavior is therefore called the “Geiger-mode” region.

As with photodiodes the wavelength region in which it is most sensitive is a product of its material properties, in particular the energy bandgap within the semiconductor. Many materials including silicon, germanium and other III-V elements have been used to fabricate SPADs for the large variety of applications that now utilize the run-away avalanche process. There is much research in this topic with activity implementing SPAD-based systems in complementary metal-oxide semiconductor (CMOS) fabrication technologies, and investigation and use of III-V material combinations for single-photon detection at dedicated wavelengths.

Photomultiplier tubes (photomultipliers or PMTs for short), members of the class of vacuum tubes, and more specifically vacuum phototubes, are extremely sensitive detectors of light in the ultraviolet, visible, and near-infrared ranges of the electromagnetic spectrum. These detectors multiply the current produced by incident light by as much as 100 million times or 108 (i.e., 160 dB), [1] in multiple dynode stages, enabling (for example) individual photons to be detected when the incident flux of light is low.

The combination of high gain, low noise, high frequency response or, equivalently, ultra-fast response, and large area of collection has maintained photomultipliers an essential place in low light level spectroscopy, confocal microscopy, Raman spectroscopy, fluorescence spectroscopy, nuclear and particle physics, astronomy, medical diagnostics including blood tests, medical imaging, motion picture film scanning (telecine), radar jamming, and high-end image scanners known as drum scanners. Elements of photomultiplier technology, when integrated differently, are the basis of night vision devices. Research that analyzes light scattering, such as the study of polymers in solution, often uses a laser and a PMT to collect the scattered light data.

Semiconductor devices, particularly silicon photomultipliers and APDs, are alternatives to classical photomultipliers; however, photomultipliers are uniquely well-suited for applications requiring low-noise, high-sensitivity detection of light that is imperfectly collimated.

The following paragraphs provide various examples of the embodiments disclosed herein.

Example 1 includes a system package, including circuitries including circuit elements; and a plurality of connection pins including low-voltage pins; input/output (IO) pins arranged in regions proximate edges of the system package; and high-voltage pins arranged in an inner region of the system package away from all edges of the system package.

In Example 2, the system package of example 1 can optionally include where the high-voltage pins are configured to output a voltage between 0 and −400 Volt (V).

In Example 3, the system package of any of examples 1-2 can optionally include where the high-voltage pins are configured to output a voltage at −375 Volt (V).

In Example 4, the system package of any of examples 1-3 can optionally include where a distance between an individual high-voltage pin of the high-voltage pins and an edge of the system package satisfies a predetermined creepage distance associated with a voltage output by the individual high-voltage pin.

In Example 5, the system package of any of examples 1-4 can optionally include where the plurality of connection pins further includes ground pins in a region of the system package between the IO pins and the high-voltage pins.

In Example 6, the system package of any of examples 1-5 can optionally include where the IO pins include at least one of a control pin or a data signal pin associated with serial communication.

In Example 7, the system package of any of examples 1-6 can optionally include where the IO pins include at least one control pin for controlling an output voltage at the high-voltage pins.

In Example 8, the system package of any of examples 1-7 can optionally include where the IO pins include at least one control pin for controlling a current associated with an output voltage at an individual pin of the high-voltage pins.

In Example 9, the system package of any of examples 1-8 can optionally include where the IO pins include at least one readout pin for reading a configuration associated with an output voltage at the high-voltage pins.

In Example 10, the system package of any of examples 1-9 can optionally include where the low-voltage pins include at least one input voltage pin for receiving an input voltage, and an output voltage at an individual high-voltage pin of the high-voltage pins is based at least in part on a voltage level of the input voltage.

In Example 11, the system package of any of examples 1-10 can optionally include a temperature indicator.

In Example 12, the system package of any of examples 1-11 can optionally include where the system package is a ball grid array (BGA) package.

Example 13 includes an integrated circuit (IC) package, including a plurality of IC devices including a negative power boost IC device; and a plurality of connection pins on a common plane of the system package, where the plurality of connection pins includes one or more low-voltage pins to receive a first voltage, the one or more low-voltage pins coupled to an input of the negative power boost IC device, one or more high-voltage pins to output a second voltage based on the first voltage, the one or more high-voltage pins coupled to an output of the negative power boost IC device and disposed on an inner region of the common plane away from edges of the system package.

In Example 14, the system package of example 13 can optionally include where the second voltage is between 0 and −400 Volt (V).

In Example 15, the system package of any of examples 13-14 can optionally include where the plurality of connection pins further includes a group of ground pins surrounding the high-voltage pins.

In Example 16, the system package of any of examples 13-15 can optionally include where the plurality of IC devices further includes a serial peripheral interface (SPI) IC device.

In Example 17, the system package of any of examples 13-16 can optionally include where the plurality of IC devices further include at least one of an analog-to-digital converter (ADC) or a digital-to-analog converter (DAC).

In Example 18, the system package of any of examples 13-17 can optionally include where the plurality of IC devices further include at least one of an amplifier IC device or a comparator IC device.

Example 19 includes a system including an integrated circuit (IC) package including an inverting power boost converter; one or more input voltage pins coupled to an input of the inverting power boost converter; and one or more high-voltage pins coupled to an output of the inverting power boost converter, where none of the one or more high-voltage pins are proximate to an outer edge of the system package; and one or more avalanche photodiodes (APDs) coupled to at least one of the one or more high-voltage pins.

In Example 20, the system of example 19 can optionally include where the system package further includes a temperature indicator component.

In Example 21, the system of any of examples 1-2 can optionally include further including a light detection and ranging (LIDAR) device, where the one or more APDs are part of the LIDAR device.

In general, an example apparatus and/or method comprises HV pins not disposed at the edge.

According to anyone of the preceding examples, the apparatus and/or method further comprises a plurality of signal pins.

According to anyone of the preceding examples, the apparatus and/or method further comprises a plurality of Vin pins.

According to anyone of the preceding examples, the apparatus and/or method further comprises a plurality of control pins.

According to anyone of the preceding examples, the apparatus and/or method further comprises a ground region separating the HV pins from at least one of the pluralities of control, Vin and signal pins.

According to anyone of the preceding examples, wherein the ground region is sufficiently large enough to overcome creepage distance limitations, standards and/or specifications.

According to anyone of the preceding examples, wherein no pins are skipped in at least one of the pluralities of control, Vin and signal pins.

According to anyone of the preceding examples, wherein the of the HV pins from the edge of the is at least the prerequisite creepage.

According to anyone of the preceding examples, wherein the of the HV pins from the edge is substantially the same as the predetermined creepage.

According to anyone of the preceding examples, wherein the of the HV pins from the edge is substantially the same as the predetermined clearance.

According to anyone of the preceding examples, wherein the HV pins output is configured to be suitable to produce a potential range from 0V to −400V.

According to anyone of the preceding examples, wherein the HV pins output is configured to be suitable to produce a potential of −375V.

According to anyone of the preceding examples, the apparatus and/or method further comprises an SPI interface.

According to anyone of the preceding examples, the apparatus and/or method further comprises a temperature indicator.

The above description of illustrated embodiments, including what is described in the Abstract, is not intended to be exhaustive or limiting as to the precise forms disclosed. While specific implementations of, and examples for, various embodiments or concepts are described herein for illustrative purposes, various equivalent modifications may be possible, as those skilled in the relevant art will recognize. These modifications may be made in light of the above detailed description, the Abstract, the Figures, or the claims.

Having thus described several aspects and embodiments of the technology of this application, it is to be appreciated that various alterations, modifications, and improvements will readily occur to those of ordinary skill in the art. Such alterations, modifications, and improvements are intended to be within the spirit and scope of the technology described in the application. For example, those of ordinary skill in the art will readily envision a variety of other means and/or structures for performing the function and/or obtaining the results and/or one or more of the advantages described herein, and each of such variations and/or modifications is deemed to be within the scope of the embodiments described herein.

Those skilled in the art will recognize, or be able to ascertain using no more than routine experimentation, many equivalents to the specific embodiments described herein. It is, therefore, to be understood that the foregoing embodiments are presented by way of example only and that, within the scope of the appended claims and equivalents thereto, inventive embodiments may be practiced otherwise than as specifically described. In addition, any combination of two or more features, systems, articles, materials, kits, and/or methods described herein, if such features, systems, articles, materials, kits, and/or methods are not mutually inconsistent, is included within the scope of the present disclosure.

The foregoing outlines features of one or more embodiments of the subject matter disclosed herein. These embodiments are provided to enable a person having ordinary skill in the art (PHOSITA) to better understand various aspects of the present disclosure. Certain well-understood terms, as well as underlying technologies and/or standards may be referenced without being described in detail. It is anticipated that the PHOSITA will possess or have access to background knowledge or information in those technologies and standards sufficient to practice the teachings of the present disclosure.

The PHOSITA will appreciate that they may readily use the present disclosure as a basis for designing or modifying other processes, structures, or variations for carrying out the same purposes and/or achieving the same advantages of the embodiments introduced herein. The PHOSITA will also recognize that such equivalent constructions do not depart from the spirit and scope of the present disclosure, and that they may make various changes, substitutions, and alterations herein without departing from the spirit and scope of the present disclosure.

The above-described embodiments may be implemented in any of numerous ways. One or more aspects and embodiments of the present application involving the performance of processes or methods may utilize program instructions executable by a device (e.g., a computer, a processor, or other device) to perform, or control performance of, the processes or methods.

In this respect, various inventive concepts may be embodied as a computer readable storage medium (or multiple computer readable storage media) (e.g., a computer memory, one or more floppy discs, compact discs, optical discs, magnetic tapes, flash memories, circuit configurations in Field Programmable Gate Arrays or other semiconductor devices, or other tangible computer storage medium) encoded with one or more programs that, when executed on one or more computers or other processors, perform methods that implement one or more of the various embodiments described above.

The computer readable medium or media may be transportable, such that the program or programs stored thereon may be loaded onto one or more different computers or other processors to implement various ones of the aspects described above. In some embodiments, computer readable media may be non-transitory media.

Note that the activities discussed above with reference to the FIGURES which are applicable to any integrated circuit that involves signal processing (for example, gesture signal processing, video signal processing, audio signal processing, analog-to-digital conversion, digital-to-analog conversion), particularly those that can execute specialized software programs or algorithms, some of which may be associated with processing digitized real-time data.

In some cases, the teachings of the present disclosure may be encoded into one or more tangible, non-transitory computer-readable mediums having stored thereon executable instructions that, when executed, instruct a programmable device (such as a processor or digital signal processor (DSP)) to perform the methods or functions disclosed herein. In cases where the teachings herein are embodied at least partly in a hardware device (such as an application-specific integrated circuit (ASIC), IP block, or SoC), a non-transitory medium could include a hardware device hardware-programmed with logic to perform the methods or functions disclosed herein. The teachings could also be practiced in the form of Register Transfer Level (RTL) or other hardware description language such as very high-speed integrated circuit hardware description language (VHDL) or Verilog, which can be used to program a fabrication process to produce the hardware elements disclosed.

In example implementations, at least some portions of the processing activities outlined herein may also be implemented in software. In some embodiments, one or more of these features may be implemented in hardware provided external to the elements of the disclosed figures, or consolidated in any appropriate manner to achieve the intended functionality. The various components may include software (or reciprocating software) that can coordinate in order to achieve the operations as outlined herein. In still other embodiments, these elements may include any suitable algorithms, hardware, software, components, modules, interfaces, or objects that facilitate the operations thereof.

Any suitably-configured processor component can execute any type of instructions associated with the data to achieve the operations detailed herein. Any processor disclosed herein could transform an element or an article (for example, data) from one state or thing to another state or thing. In another example, some activities outlined herein may be implemented with fixed logic or programmable logic (for example, software and/or computer instructions executed by a processor) and the elements identified herein could be some type of a programmable processor, programmable digital logic (for example, a field programmable gate array (FPGA), an erasable programmable read only memory (EPROM), an electrically erasable programmable read only memory (EEPROM)), an ASIC that includes digital logic, software, code, electronic instructions, flash memory, optical disks, CD-ROMs, DVD ROMs, magnetic or optical cards, other types of machine-readable mediums suitable for storing electronic instructions, or any suitable combination thereof.

In operation, processors may store information in any suitable type of non-transitory storage medium (for example, random access memory (RAM), read only memory (ROM), FPGA, EPROM, electrically erasable programmable ROM (EEPROM), etc.), software, hardware, or in any other suitable component, device, element, or object where appropriate and based on particular needs. Further, the information being tracked, sent, received, or stored in a processor could be provided in any database, register, table, cache, queue, control list, or storage structure, based on particular needs and implementations, all of which could be referenced in any suitable timeframe.

Any of the memory items discussed herein should be construed as being encompassed within the broad term ‘memory.’ Similarly, any of the potential processing elements, modules, and machines described herein should be construed as being encompassed within the broad term ‘microprocessor’ or ‘processor.’ Furthermore, in various embodiments, the processors, memories, network cards, buses, storage devices, related peripherals, and other hardware elements described herein may be realized by a processor, memory, and other related devices configured by software or firmware to emulate or virtualize the functions of those hardware elements.

Further, it should be appreciated that a computer may be embodied in any of a number of forms, such as a rack-mounted computer, a desktop computer, a laptop computer, or a tablet computer, as non-limiting examples. Additionally, a computer may be embedded in a device not generally regarded as a computer but with suitable processing capabilities, including a personal digital assistant (PDA), a smart phone, a mobile phone, an iPad, or any other suitable portable or fixed electronic device.

Also, a computer may have one or more input and output devices. These devices can be used, among other things, to present a user interface. Examples of output devices that may be used to provide a user interface include printers or display screens for visual presentation of output and speakers or other sound generating devices for audible presentation of output. Examples of input devices that may be used for a user interface include keyboards, and pointing devices, such as mice, touch pads, and digitizing tablets. As another example, a computer may receive input information through speech recognition or in other audible formats.

Such computers may be interconnected by one or more networks in any suitable form, including a local area network or a wide area network, such as an enterprise network, and intelligent network (IN) or the Internet. Such networks may be based on any suitable technology and may operate according to any suitable protocol and may include wireless networks or wired networks.

Computer-executable instructions may be in many forms, such as program modules, executed by one or more computers or other devices. Generally, program modules include routines, programs, objects, components, data structures, etc. that performs particular tasks or implement particular abstract data types. Typically, the functionality of the program modules may be combined or distributed as desired in various embodiments.

The terms “program” or “software” are used herein in a generic sense to refer to any type of computer code or set of computer-executable instructions that may be employed to program a computer or other processor to implement various aspects as described above. Additionally, it should be appreciated that according to one aspect, one or more computer programs that when executed perform methods of the present application need not reside on a single computer or processor, but may be distributed in a modular fashion among a number of different computers or processors to implement various aspects of the present application.

Also, data structures may be stored in computer-readable media in any suitable form. For simplicity of illustration, data structures may be shown to have fields that are related through location in the data structure. Such relationships may likewise be achieved by assigning storage for the fields with locations in a computer-readable medium that convey relationship between the fields. However, any suitable mechanism may be used to establish a relationship between information in fields of a data structure, including through the use of pointers, tags or other mechanisms that establish relationship between data elements.

When implemented in software, the software code may be executed on any suitable processor or collection of processors, whether provided in a single computer or distributed among multiple computers.

Computer program logic implementing all or part of the functionality described herein is embodied in various forms, including, but in no way limited to, a source code form, a computer executable form, a hardware description form, and various intermediate forms (for example, mask works, or forms generated by an assembler, compiler, linker, or locator). In an example, source code includes a series of computer program instructions implemented in various programming languages, such as an object code, an assembly language, or a high-level language such as OpenCL, RTL, Verilog, VHDL, Fortran, C, C++, JAVA, or HTML for use with various operating systems or operating environments. The source code may define and use various data structures and communication messages. The source code may be in a computer executable form (e.g., via an interpreter), or the source code may be converted (e.g., via a translator, assembler, or compiler) into a computer executable form.

In some embodiments, any number of electrical circuits of the FIGURES may be implemented on a board of an associated electronic device. The board can be a general circuit board that can hold various components of the internal electronic system of the electronic device and, further, provide connectors for other peripherals. More specifically, the board can provide the electrical connections by which the other components of the system can communicate electrically. Any suitable processors (inclusive of digital signal processors, microprocessors, supporting chipsets, etc.), memory elements, etc. can be suitably coupled to the board based on particular configuration needs, processing demands, computer designs, etc.

Other components such as external storage, additional sensors, controllers for audio/video display, and peripheral devices may be attached to the board as plug-in cards, via cables, or integrated into the board itself. In another example embodiment, the electrical circuits of the FIGURES may be implemented as standalone modules (e.g., a device with associated components and circuitry configured to perform a specific application or function) or implemented as plug-in modules into application-specific hardware of electronic devices.

Note that with the numerous examples provided herein, interaction may be described in terms of two, three, four, or more electrical components. However, this has been done for purposes of clarity and example only. It should be appreciated that the system can be consolidated in any suitable manner. Along similar design alternatives, any of the illustrated components, modules, and elements of the FIGURES may be combined in various possible configurations, all of which are clearly within the broad scope of this disclosure.

In certain cases, it may be easier to describe one or more of the functionalities of a given set of flows by only referencing a limited number of electrical elements. It should be appreciated that the electrical circuits of the FIGURES and its teachings are readily scalable and can accommodate a large number of components, as well as more complicated/sophisticated arrangements and configurations. Accordingly, the examples provided should not limit the scope or inhibit the broad teachings of the electrical circuits as potentially applied to a myriad of other architectures.

Also, as described, some aspects may be embodied as one or more methods. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms. Unless the context clearly requires otherwise, throughout the description and the claims:

“comprise,” “comprising,” and the like are to be construed in an inclusive sense, as opposed to an exclusive or exhaustive sense; that is to say, in the sense of “including, but not limited to”.

“connected,” “coupled,” or any variant thereof, means any connection or coupling, either direct or indirect, between two or more elements; the coupling or connection between the elements can be physical, logical, or a combination thereof.

“herein,” “above,” “below,” and words of similar import, when used to describe this specification shall refer to this specification as a whole and not to any particular portions of this specification.

“or,” in reference to a list of two or more items, covers all of the following interpretations of the word: any of the items in the list, all of the items in the list, and any combination of the items in the list.

the singular forms “a”, “an” and “the” also include the meaning of any appropriate plural forms.

Words that indicate directions such as “vertical”, “transverse”, “horizontal”, “upward”, “downward”, “forward”, “backward”, “inward”, “outward”, “vertical”, “transverse”, “left”, “right”, “front”, “back”, “top”, “bottom”, “below”, “above”, “under”, and the like, used in this description and any accompanying claims (where present) depend on the specific orientation of the apparatus described and illustrated. The subject matter described herein may assume various alternative orientations. Accordingly, these directional terms are not strictly defined and should not be interpreted narrowly.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined.

Elements other than those specifically identified by the “and/or” clause may optionally be present, whether related or unrelated to those elements specifically identified. Thus, as a non-limiting example, a reference to “A and/or B”, when used in conjunction with open-ended language such as “comprising” may refer, in one embodiment, to A only (optionally including elements other than B); in another embodiment, to B only (optionally including elements other than A); in yet another embodiment, to both A and B (optionally including other elements); etc.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

Thus, as a non-limiting example, “at least one of A and B” (or, equivalently, “at least one of A or B,” or, equivalently “at least one of A and/or B”) may refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

As used herein, the term “between” is to be inclusive unless indicated otherwise. For example, “between A and B” includes A and B unless indicated otherwise.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively.

Numerous other changes, substitutions, variations, alterations, and modifications may be ascertained to one skilled in the art and it is intended that the present disclosure encompass all such changes, substitutions, variations, alterations, and modifications as falling within the scope of the appended claims.

In order to assist the United States Patent and Trademark Office (USPTO) and, additionally, any readers of any patent issued on this application in interpreting the claims appended hereto, Applicant wishes to note that the Applicant: (a) does not intend any of the appended claims to invoke 35 U.S.C. § 112(f) as it exists on the date of the filing hereof unless the words “means for” or “steps for” are specifically used in the particular claims; and (b) does not intend, by any statement in the disclosure, to limit this disclosure in any way that is not otherwise reflected in the appended claims.

The present invention should therefore not be considered limited to the particular embodiments described above. Various modifications, equivalent processes, as well as numerous structures to which the present invention may be applicable, will be readily apparent to those skilled in the art to which the present invention is directed upon review of the present disclosure.

1. A system package for providing a power supply, comprising:
circuitries comprising circuit elements; and
a plurality of connection pins comprising:
low-voltage pins;
input/output (IO) pins arranged in regions proximate edges of the system package; and
high-voltage pins arranged in an inner region of the system package away from all edges of the system package.

2. The system package of claim 1, wherein the high-voltage pins are configured to output a voltage between 0 and −400 Volt (V).

3. The system package of claim 1, wherein the high-voltage pins are configured to output a voltage at −375 Volt (V).

4. The system package of claim 1, wherein a distance between an individual high-voltage pin of the high-voltage pins and an edge of the system package satisfies a predetermined creepage distance associated with a voltage output by the individual high-voltage pin.

5. The system package of claim 1, wherein the plurality of connection pins further comprises ground pins in a region of the system package between the IO pins and the high-voltage pins.

6. The system package of claim 1, wherein the IO pins comprise at least one of a control pin or a data signal pin associated with serial communication.

7. The system package of claim 1, wherein the IO pins comprise at least one control pin for controlling an output voltage at an individual high-voltage pin of the high-voltage pins.

8. The system package of claim 1, wherein the IO pins comprise at least one control pin for controlling a current associated with an output voltage at an individual high-voltage pin of the high-voltage pins.

9. The system package of claim 1, wherein the IO pins comprise at least one readout pin for reading a configuration associated with an output voltage at an individual high-voltage pin of the high-voltage pins.

10. The system package of claim 1, wherein:
the low-voltage pins comprise at least one input voltage pin for receiving an input voltage, and
an output voltage at an individual high-voltage pin of the high-voltage pins is based at least in part on a voltage level of the input voltage.

11. The system package of claim 1, further comprising a temperature indicator.

12. The system package of claim 1, wherein the system package is a ball grid array (BGA) package.

13. A system package, comprising:
a plurality of integrated circuit (IC) devices including a negative power boost IC device; and
a plurality of connection pins on a common plane of the system package, wherein the plurality of connection pins comprises:
one or more low-voltage pins to receive a first voltage, the one or more low-voltage pins coupled to an input of the negative power boost IC device,
one or more high-voltage pins to output a second voltage based on the first voltage, the one or more high-voltage pins coupled to an output of the negative power boost IC device and disposed on an inner region of the common plane away from edges of the system package.

14. The system package of claim 13, wherein the second voltage is between 0 and −400 Volt (V).

15. The system package of claim 13, wherein the plurality of connection pins further comprises a group of ground pins surrounding the high-voltage pins.

16. The system package of claim 13, wherein the plurality of IC devices further comprise a serial peripheral interface (SPI) IC device.

17. The system package of claim 13, wherein the plurality of IC devices further comprise at least one of an analog-to-digital converter (ADC) or a digital-to-analog converter (DAC).

18. The system package of claim 13, wherein the plurality of IC devices further comprise at least one of an amplifier IC device or a comparator IC device.

19. A system comprising:
a package comprising:
an inverting power boost converter;
one or more input voltage pins coupled to an input of the inverting power boost converter; and
one or more high-voltage pins coupled to an output of the inverting power boost converter, wherein none of the one or more high-voltage pins are proximate to an outer edge of the system package; and
one or more avalanche photodiodes (APDs) coupled to at least one of the one or more high-voltage pins.

20. The system of claim 19, further comprising:
a light detection and ranging (LIDAR) device, wherein the one or more APDs are part of the LIDAR device.
